(19) United States
(12) Patent Application Publication
(10) Pub. No.: US 2025/0081376 A1
(43) Pub. Date: Mar. 6, 2025

(54) COOLING STRUCTURE OF A POWER SUPPLY MODULE

(71) Applicant: Murata Manufacturing Co., Ltd., Nagaokakyo-shi, Kyoto-fu (JP)

(72) Inventors: Takami MUTO, San Jose, CA (US); Masanari TAGO, San Jose, CA (US)

(21) Appl. No.: 18/726,640

(22) PCT Filed: Jan. 24, 2023
(86) PCT No.: PCT/US2023/011418

§ 371 Date: Jul. 3, 2024

Related U.S. Application Data
(60) Provisional application No. 63/320,851, filed on Mar. 17, 2022.

(51) Int. Cl. H05K 7/14; H05K 7/20

(52) U.S. Cl. CPC H05K 7/14329; H05K 7/209

(57) ABSTRACT

A power supply module including a substrate, an electronic component provided on an upper surface of the substrate, a lower board electrically connected with the electronic component through the substrate, and an upper board electrically connected another end of the at least one pillar opposing an end of the at least one pillar that is electrically connected with the at least one lower board, the at least one upper board being electrically connected with the substrate. A pillar extends between the lower board and the upper board. The pillar includes a first end electrically connected with the lower board and a second end electrically connected with the upper board. A magnetic material is provided around a periphery of the pillar.

### CROSS REFERENCE TO RELATED APPLICATIONS

This application claims the benefit of U.S. Provisional Patent Application No. 63/320,851, filed on Mar. 17, 2022. The entire contents of this application are hereby incorporated by reference.

### BACKGROUND OF THE INVENTION

### 1. Field of the Invention

The present invention relates to power supply modules. More specifically, the present invention relates to cooling heat-generating power elements in power supply modules to thereby improve performance of the power supply module.

### 2. Description of the Related Art

Known power supply modules include heat-generating components, such as the power elements of the power supply modules. The heat-generating components are connected to heat sinks such that some of the heat generated in the heat-generating components is transferred to the heat sink which aids in dissipating the heat.

However, typical arrangements in the known power supply modules require a large amount of space, which is not desirable when miniaturization of the power supply modules is required. Further, if heat-generating power components must be placed close to inductive components, this decreases the cooling efficiency because inductive components have low thermal conductivity. When cooling efficiency is decreased, the heat-generating power components are not able to generate a high current.

JP 2020-047648 shows an inductor in a DC-DC converter. However, the core of the structure of the inductor 4i is toroidal and lacks sufficient heat dissipating capacity for high-current power components.

### SUMMARY OF THE INVENTION

To overcome the problems described above, preferred embodiments of the present invention provide a power supply module which can be miniaturized, while also having sufficient cooling such that it is still possible to generate high current.

A preferred embodiment of the present invention provide a power supply module including a substrate, an electronic component provided on an upper surface of the substrate, a lower board electrically connected with the electronic component through the substrate, and an upper board electrically connected another end of the at least one pillar opposing an end of the at least one pillar that is electrically connected with the at least one lower board, the at least one upper board being electrically connected with the substrate. A pillar extends between the lower board and the upper board. The pillar includes a first end electrically connected with the lower board and a second end electrically connected with the upper board. A magnetic material is provided around a periphery of the pillar.

The electronic component can be thermally connected with the lower board. The electronic component can be thermally connected with the lower board through a thermal conductive material. The lower board, the pillar, and the upper board can define an inductor.

The lower board can connected with the upper surface of the substrate; the lower board can include a lower-board rising portion extending upwards from the substrate, a lower-board bent portion located on an end of the lower-board rising portion, and a lower-board flat portion extending from the lower-board bent portion along a plane parallel or substantially parallel to the upper surface of the substrate; and an upper surface of the lower-board flat portion can be connected with the first end of the one pillar.

An upper surface of the electronic component can be thermally connected with a lower surface of the lower-board flat portion. Thermally conductive material can be provided between the upper surface of the electronic component and the lower surface of the lower-board flat portion.

A surface area of the lower-board flat portion can be greater than a surface area of the lower-board rising portion. A maximum height of the electronic component is the same as or smaller than a distance between a lower surface of the lower-board flat portion and the upper surface of the substrate.

The electronic component can be at least partially molded in a resin material. A maximum height of the resin material can be the same or smaller than the distance between the lower surface of the lower-board flat portion and the upper surface of the substrate.

The upper board can include an upper-board flat portion extending along a plane parallel or substantially to the upper surface of the substrate, an upper-board bent portion provided on an end of the upper-board flat portion, and an upper-board rising portion can extend from the upper-board bent portion and can be electrically connected to the substrate. A sum of the maximum height of the electronic component, a maximum thickness of the lower-board flat portion, and a maximum thickness of the pillar can be the same as a total distance between a lower surface of the upper-board flat portion and the upper surface of the substrate. A total surface area of the upper-board flat portion can be larger than a total surface area of the upper-board rising portion.

The pillar can have a cylindrical shape. The electronic component can include a field-effect transistor. The module can further include an additional pillar, wherein the pillar and the additional pillar can be arranged in a straight line which extends in a direction that crosses an extending direction of the lower board.

A preferred embodiment of the present invention provides a power supply module including a first substrate and a second substrate; a first electronic component provided on an upper surface of the first substrate; a first lower board electrically connected with the first electronic component through the first substrate; a first upper board electrically connected with the first substrate; a first pillar that extends between the first lower board and the first upper board and that includes a first end electrically connected with the first lower board and a second end electrically connected with the first upper board; a first magnetic material provided around the first pillar; a second electronic component provided on an upper surface of the second substrate; a second lower board electrically connected with the second electronic component through the second substrate; a second upper board electrically connected with the second substrate; a second pillar that extends between the second lower board and the second upper board and that includes a first end electrically connected with the second lower board and a second end electrically connected with the second upper board; and a second magnetic material provided around the second pillar. The first lower board, the first pillar, the first upper board, the second lower board, the second pillar, and the second upper board are magnetically connected together.

The first magnetic material and the second magnetic material can be fixed together. The first magnetic material and the second magnetic material can be provided together as a single monolithic member.

The above and other features, elements, characteristics, steps, and advantages of the present invention will become more apparent from the following detailed description of preferred embodiments of the present invention with reference to the attached drawings.

### BRIEF DESCRIPTION OF THE DRAWINGS

FIG. 1 shows a side view of a power supply module according to a first preferred embodiment of the present invention.

FIGS. 2A-2D show perspective views of portions of the power supply module according to the first preferred embodiment of the present invention.

FIG. 2E shows a perspective view of the power supply module according to the first preferred embodiment of the present invention, and FIG. 2F shows a circuit diagram of the power supply module according to the first preferred embodiment of the present invention.

FIG. 3 shows a perspective view of a power supply module according to a modification of the first preferred embodiment of the present invention.

FIGS. 4A and 4B show perspective views of the power supply module according to a second preferred embodiment of the present invention.

FIG. 5 shows a perspective view of the power supply module according to a third preferred embodiment of the present invention.

FIGS. 6A and 6B show perspective views of the power supply module according to a fourth preferred embodiment of the present invention.

FIGS. 6C and 6D show perspective views of portions of the power supply module according to the fourth preferred embodiment of the present invention.

FIGS. 7A and 7B show perspective views of the power supply module according to a fifth preferred embodiment of the present invention.

FIG. 7C shows a perspective view of a power supply module according to a modification of the fifth preferred embodiment of the present invention.

FIG. 8A shows a perspective view of a power supply module according to a sixth preferred embodiment of the present invention.

FIGS. 8B and 8C show perspective views of portions of the power supply module according to the sixth preferred embodiment of the present invention.

FIG. 9 shows a perspective view of a power supply module according to a seventh preferred embodiment of the present invention.

FIG. 10 shows a perspective view of a power supply module according to an eighth preferred embodiment of the present invention.

### DETAILED DESCRIPTION OF PREFERRED EMBODIMENTS

### First Preferred Embodiment

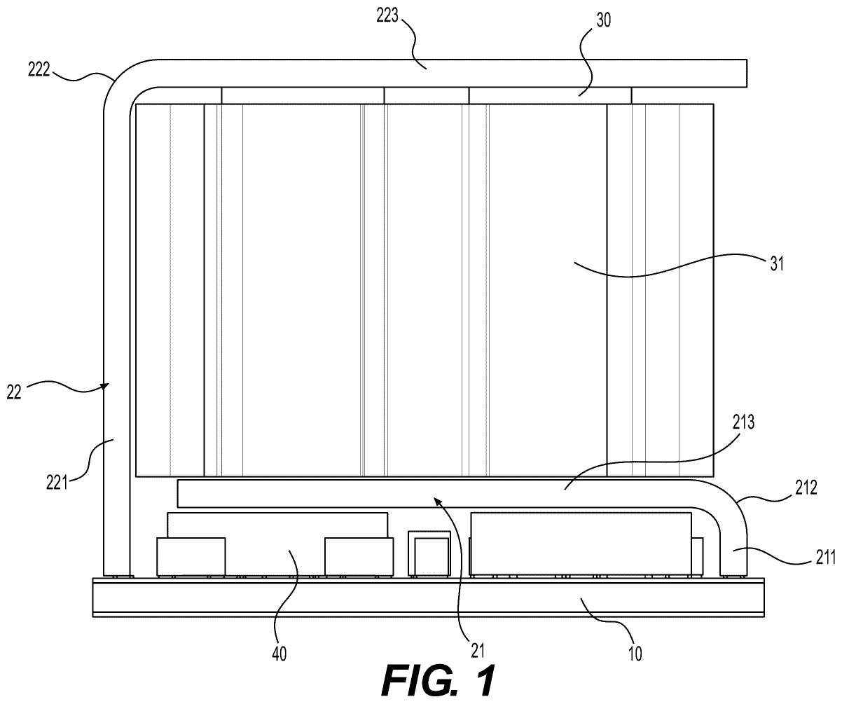

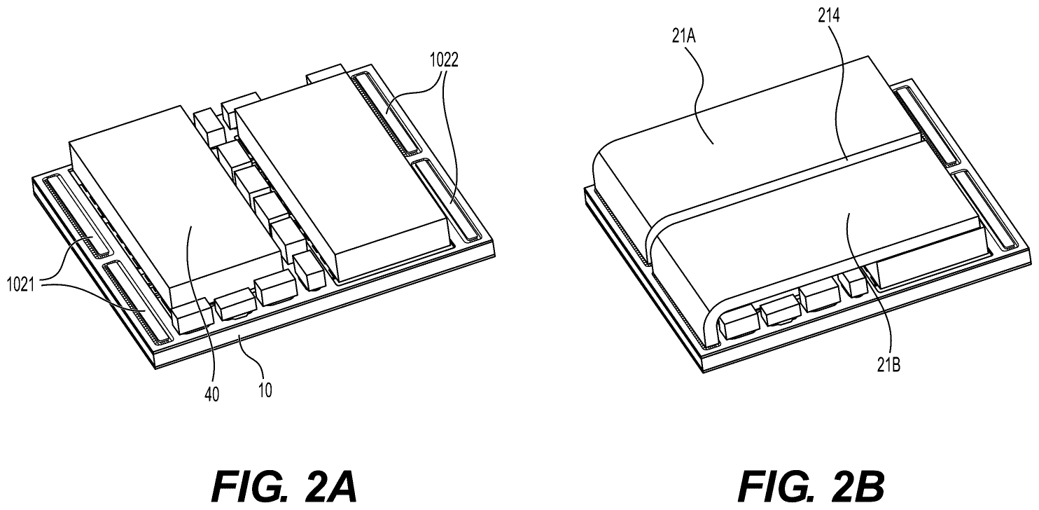

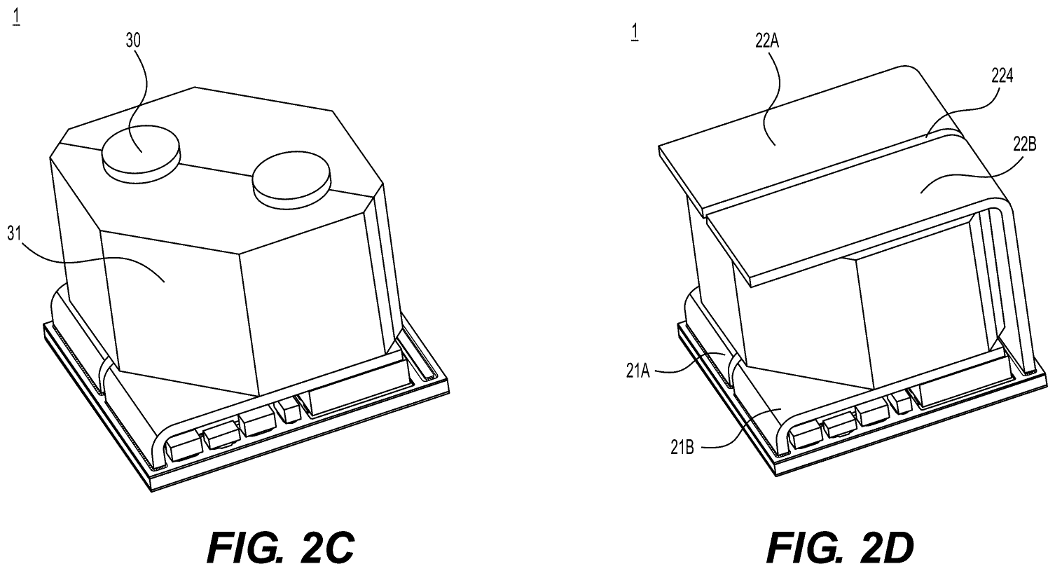

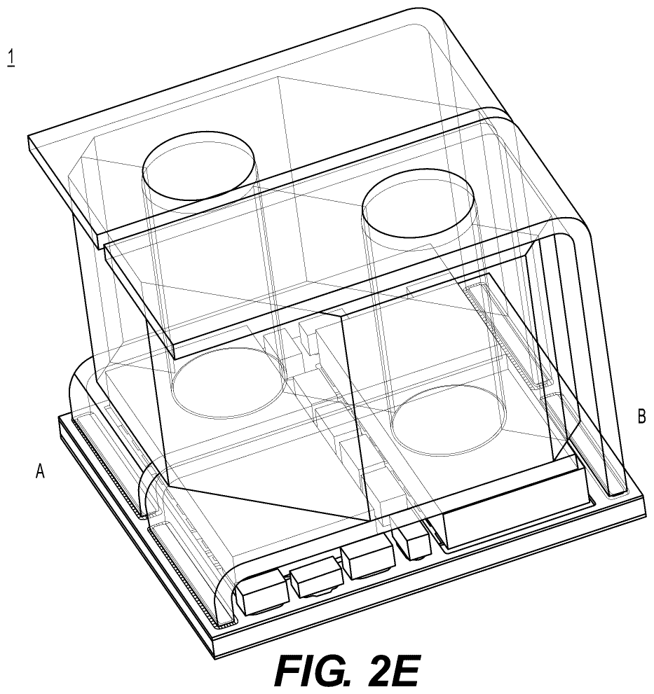

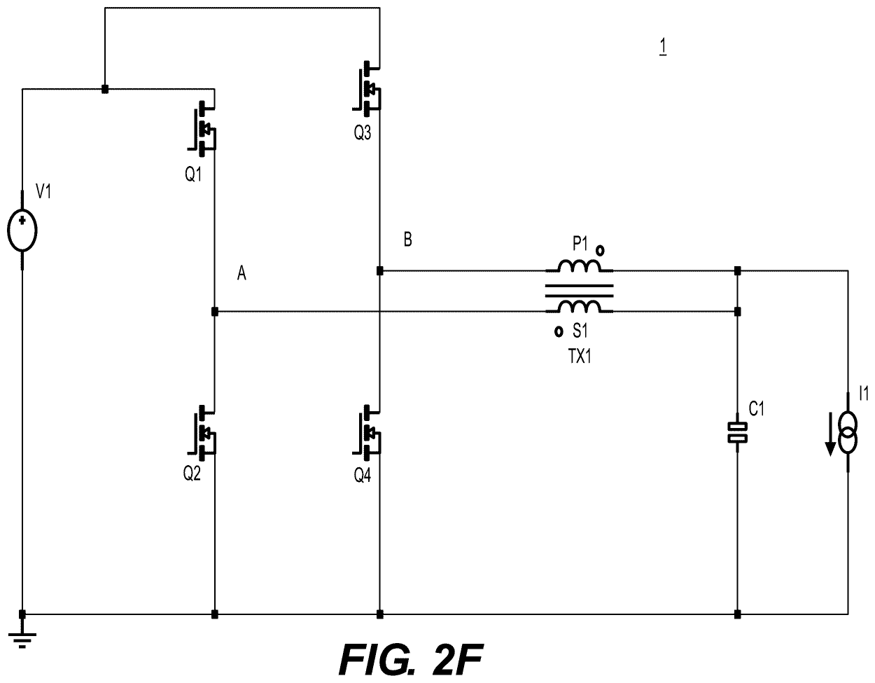

A power supply module 1 according to a first preferred embodiment of the present invention will be described with reference to FIGS. 1-2F. FIG. 1 is a side view of a power supply module 1 according to a first preferred embodiment of the present invention. FIGS. 2A-2D are perspective views of portions of the power supply module 1 according to the first preferred embodiment of the present invention. FIG. 2E is a perspective view of the power supply module 1 according to the first preferred embodiment of the present invention. FIG. 2F is a circuit diagram of the power supply module 1 according to the first preferred embodiment of the present invention.

As shown in FIG. 1, a power supply module 1 can include a substrate 10, one or more electrical components 40 on a surface of the substrate 10, a lower board 21 extending from the upper surface of the substrate 10 to extend over the electrical components 40, one or more pillars 30 extending from an upper surface of the lower board 21, magnetic material 31 surrounding the one or more pillars 30, and an upper board 22 extending from the surface of the substrate 10 to extend over a top of the one or more pillars 30. The electrical components 40 can include, for example, power components (e.g., field-effect transistors), capacitors, resistors, etc.

The lower board 21 can include a pair of lower board portions 21A and 21B that are spaced apart from one another with a gap 214 therebetween, as shown in FIG. 2B. The lower board 21 can include a lower-board rising portion 211, a lower-board bend portion 212, and a lower-board flat portion 213. The lower-board rising portion 211 extends perpendicularly or substantially perpendicularly within manufacturing and/or measurement tolerances to the upper surface of the substrate 10, and the lower-board flat portion 213 extends parallel or substantially parallel within manufacturing and/or measurement tolerances with the upper surface of the substrate 10. A surface area of the lower-board flat portion 213 can be greater than a surface area of the lower-board rising portion 211. However, it is also possible for the surface area of the lower-board flat portion 213 to be the same as or smaller than the surface area of the lower-board rising portion 211. A bottom of the lower-board rising portion 211 can be fixed into openings 1021 defined in the substrate 10. The lower board 21 can be electrically connected to one or more of the electrical components 40 through solder and/or traces defined on or in the substrate 10.

The upper board 22 can include a pair of upper board portions 22A and 22B which are spaced apart from one another with a gap 224 therebetween, as shown in FIG. 2D. The upper board 22 can include an upper-board rising portion 221, an upper-board bend portion 222, and an upper-board flat portion 223. The upper-board rising portion 221 extends perpendicularly or substantially perpendicularly within manufacturing and/or measurement tolerances to the upper surface of the substrate 10, and the upper-board flat portion 223 extends parallel or substantially parallel within manufacturing and/or measurement tolerances with the upper surface of the substrate 10. A bottom of the upper-board rising portion 221 can be fixed into openings 1022 defined in the substrate 10. A total surface area of the upper-board flat portion 223 can be greater than a total surface area of the upper-board rising portion 221. However, it is also possible for the total surface area of the upper-board flat portion 223 to be the same or smaller than the total surface area of the upper-board rising portion 223. The upper board 22 can be electrically connected to one or more of the electrical components 40 through solder and/or traces defined on or in the substrate 10.

At least one pillar 30 extends from the lower-board flat portion 213 to the upper-board flat portion 223. The lower board 21 and the upper board 22 are electrically connected to one another through the least one pillar 30. As shown in FIG. 2C, the at least one pillar 30 can include a pair of pillars, for example. But a different number of pillars can be used. The at least one pillar 30 can be cylindrical in shape, but any other shape could be used. The at least one pillar 30 is surrounded by magnetic material 31. The lower board 21, the upper board 22, the least one pillar 30, and the magnetic material 31 together can define one or more inductors. Further, the structure of the lower board 21, the upper board 22, the least one pillar 30, and the magnetic material 31 can define a heat sink that can dissipate heat generated within the power supply module 1.

A maximum height of at least one of the electrical components 40 is the same or substantially the same as a distance between the lower-board flat portion 213 and an upper surface of the substrate 10. Further, the maximum height of the at least one of the electrical components 40 may be smaller than the distance between the lower-board flat portion 213 and the upper surface of the substrate 10.

FIGS. 2E and 2F show an example of a circuit arrangement which could be provided in the power supply module 1. The circuit arrangement can include a transformer TX1 which is provided between pairs of transistors Q1, Q2 and transistors Q3, Q4. A primary winding P1 includes a node B, and a secondary winding S1 includes a node A. Node B is connected between transistors Q3 and Q4 and corresponds to a connection of the upper board 22 to the circuit board 10. Node A is connected between transistors Q1 and Q2 and corresponds to a connection of the lower board 21 to the circuit board 10. Ends of the primary winding P1 and the secondary winding S1 which are not connected to Nodes A and B are connected to a capacitor C1 and to a current source 11 connected in parallel between the primary winding P1 and the secondary winding S1 and ground. The pairs of transistors Q1, Q2 and transistors Q3, Q4 are also connected in parallel between the voltage source V1 and ground.

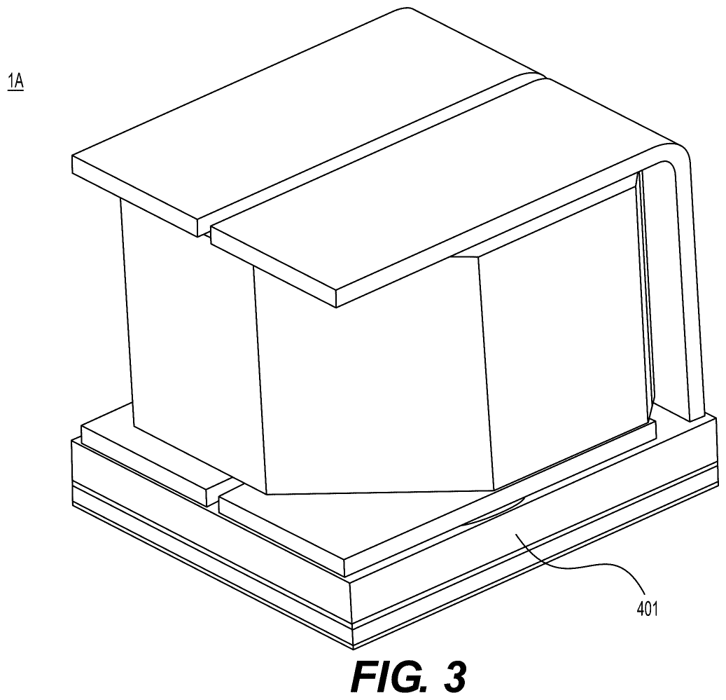

FIG. 3 shows a power supply module 1A according to a modification of the first preferred embodiment of the present invention. The power supply module 1A according to the modification of the first preferred embodiment can be different from the power supply module 1 according to the first preferred embodiment in that the electrical components 40 on the substrate 10 are encapsulated in a thermally conductive resin material 401. Further, the thermally conductive resin material 401 provides support for the lower board 21 to thereby help stabilize the structure of the power supply module 1A. A maximum height of at least one of the electrical components 40 can be substantially the same or smaller than a maximum height of the resin material 401. By encapsulating the electrical components 40 in the resin material 401, it is possible to provide better heat transference between the substrate 10, the electrical components 40, and the lower board 21 while simultaneously increasing stability.

### Second Preferred Embodiment

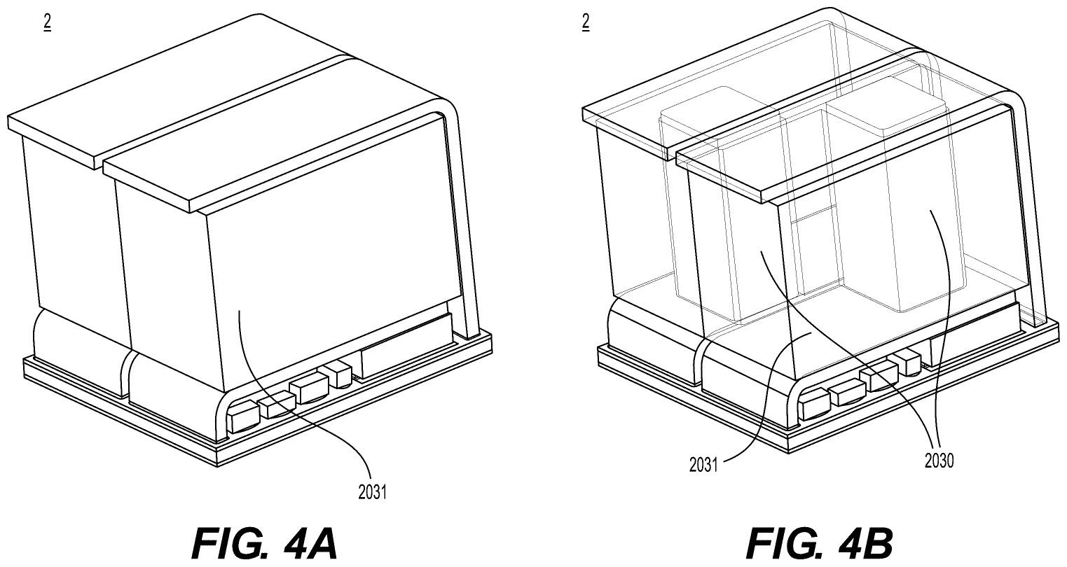

A power supply module 2 according to a second preferred embodiment of the present invention will be described with reference to FIGS. 4A and 4B. FIG. 4A is a perspective view of an example of a power supply module 2 according to the second preferred embodiment of the present invention. FIG. 4B is another perspective view of an example of a power supply module 2 according to the second preferred embodiment of the present invention which is semi-transparent to show internal shapes of the components of the power supply module 2.

As illustrated in FIGS. 4A and 4B, the power supply module 2 according to the second preferred embodiment can be different from the power supply module 1 according to the first preferred embodiment in that the pillar 2030 and the magnetic material 2031 can be rectangular or cubic in shape. Further, it is also possible for the pillar 2030 to be polygonal (may be a pentagon, hexagon, etc.). Other configurations of the power supply module 2 according to the second preferred embodiment can be the same as those of the power supply module 1 according to the first preferred embodiment, and a description of the same portions is omitted for the sake of brevity.

### Third Preferred Embodiment

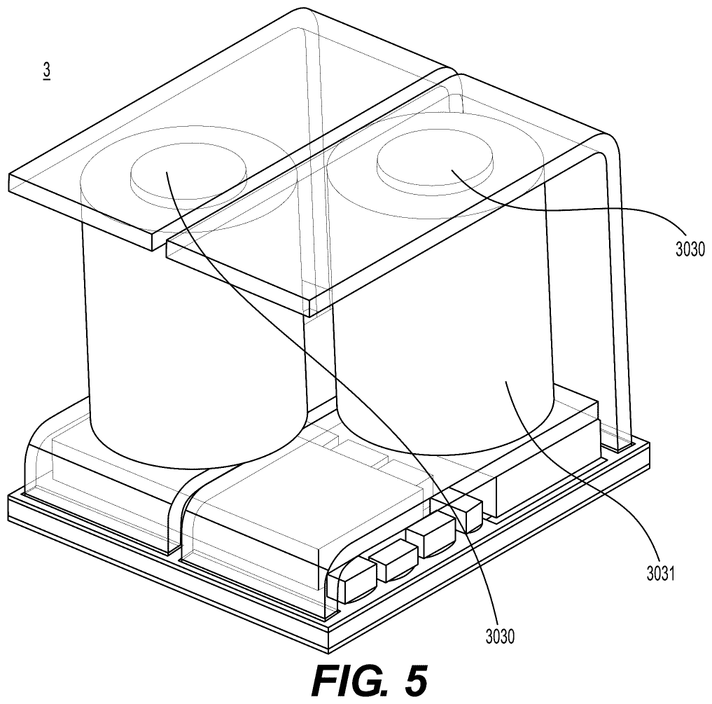

A power supply module 3 according to a third preferred embodiment of the present invention will be described with reference to FIG. 5. FIG. 5 is a perspective view of an example of a power supply module 3 according to the third preferred embodiment of the present invention which is semi-transparent to show internal shapes of the components of the power supply module 3.

As illustrated in FIG. 5, the power supply module 3 according to the third preferred embodiment can be different from the power supply module 1 according to the first preferred embodiment in that the pillar 30 is surrounded by magnetic material 2031 which can be columnar or cylindrical in shape. Other configurations of the power supply module 3 according to the third preferred embodiment can be the same as those of the power supply module 1 according to the first preferred embodiment, and a description of the same portions is omitted for the sake of brevity.

### Fourth Preferred Embodiment

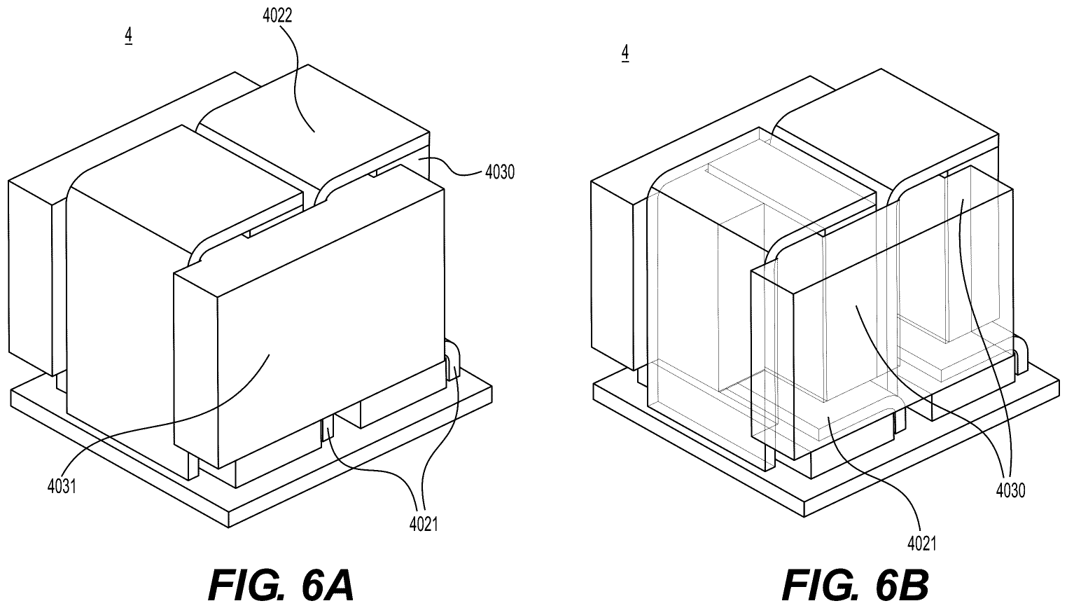

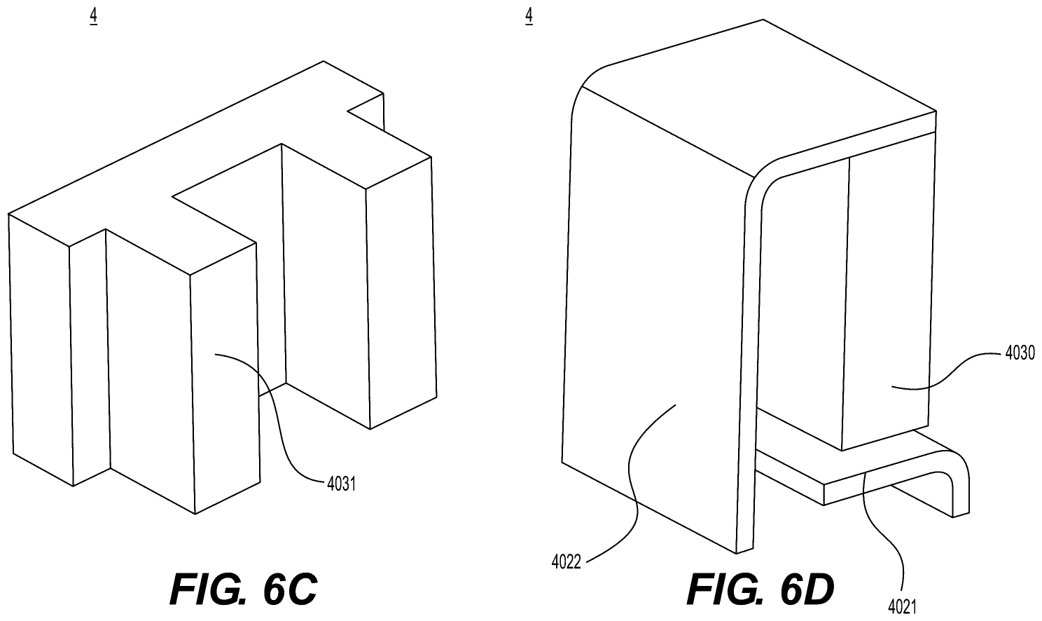

A power supply module 4 according to a fourth preferred embodiment of the present invention will be described with reference to FIGS. 6A-6D. FIGS. 6A and 6B are perspective views of the power supply module 4 according to a fourth preferred embodiment of the present invention. FIGS. 6C and 6D show perspective views of portions of the power supply module 4 according to the fourth preferred embodiment of the present invention.

As illustrated in FIGS. 6A-6D, the power supply module 4 according to the fourth preferred embodiment can be different from the power supply module 1 according to the first preferred embodiment in that the pillar 4030 is surrounded by magnetic material 4031 which can be rectangular or cubic in shape. Further, the magnetic material 4031 can include separately provided structures having the shape of the Greek letter pi (It), and the lower board 4021 and the upper board 4022 can be defined by pairs of individual structures which only directly contact the upper and the lower surfaces of the corresponding pillars 4030. Other configurations of the power supply module 4 according to the fourth preferred embodiment can be the same as those of the power supply module 1 according to the first preferred embodiment, and a description of the same portions is omitted for the sake of brevity.

### Fifth Preferred Embodiment

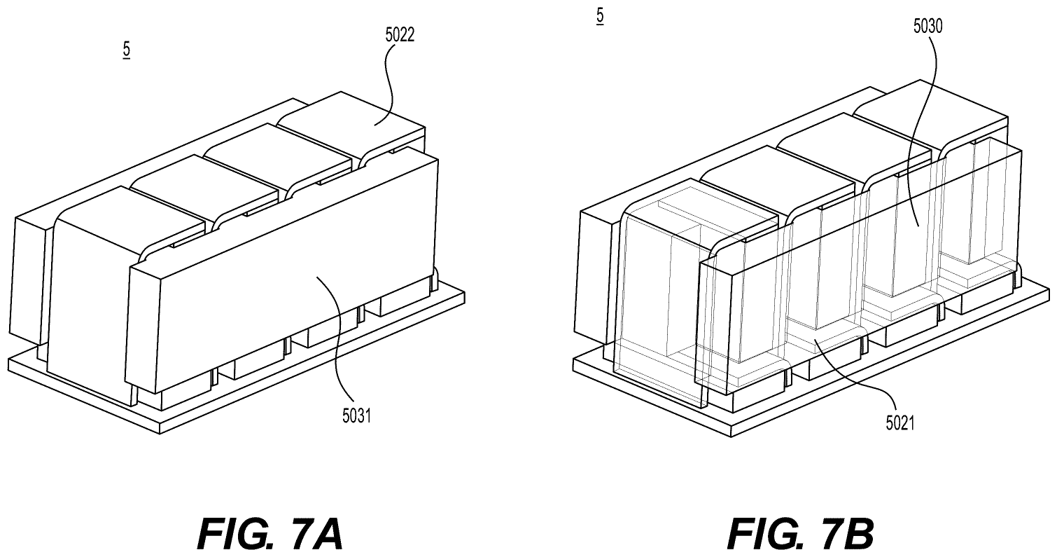

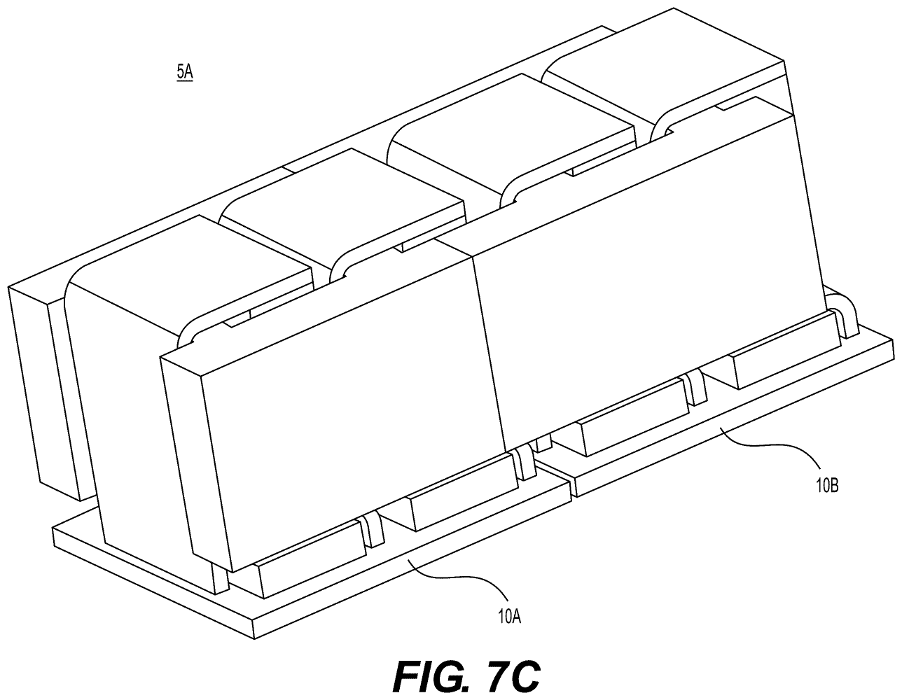

A power supply module 5 according to a fifth preferred embodiment of the present invention will be described with reference to FIGS. 7A and 7B. FIGS. 7A and 7B are perspective views of the power supply module 5 according to a fifth preferred embodiment of the present invention.

As illustrated in FIGS. 7A and 7B, the power supply module 5 according to the fifth preferred embodiment can be different from the power supply module 1 according to the first preferred embodiment in that multiple pillars 5030 which can be rectangular or cubic in shape are surrounded by magnetic material 5031 which can include separately provided structures having the shape of a single long side with multiple perpendicular projections which extend between pairs of the pillars 5030. Further, the lower board 5021 and the upper board 5022 are defined by multiple individual structures which only directly contact the upper and the lower surfaces of the corresponding pillars 5030. For example, four perpendicular projections of the magnetic material 5031 can be provided adjacent to four of the pillars 5030. Other configurations of the power supply module 5 according to the fifth preferred embodiment can be the same as those of the power supply module 1 according to the first preferred embodiment, and a description of the same portions is omitted for the sake of brevity. By increasing the number of inductors (corresponding to the pillars 5030 and the magnetic material 5031) in the power supply module 5 according to the fifth preferred embodiment is greater than that in the power supply module 1 according to the first preferred embodiment, it is possible to improve performance in the power supply module 5 according to the fifth preferred embodiment as compared to the power supply module 1 according to the first preferred embodiment.

FIG. 7C shows a power supply module 5A according to a modification of the fifth preferred embodiment of the present invention. The power supply module 5A according to the modification of the fifth preferred embodiment can be different from the power supply module 5 according to the fifth preferred embodiment in that the magnetic material 5031 is defined by multiple structures having the shape of the Greek letter pi (x). Further, a pair of substrates 10A and 10B are provided rather than a single substrate. As with the power supply module 5, increasing the number of inductors in power supply module 5A can improve performance in the power supply module 5A.

### Sixth Preferred Embodiment

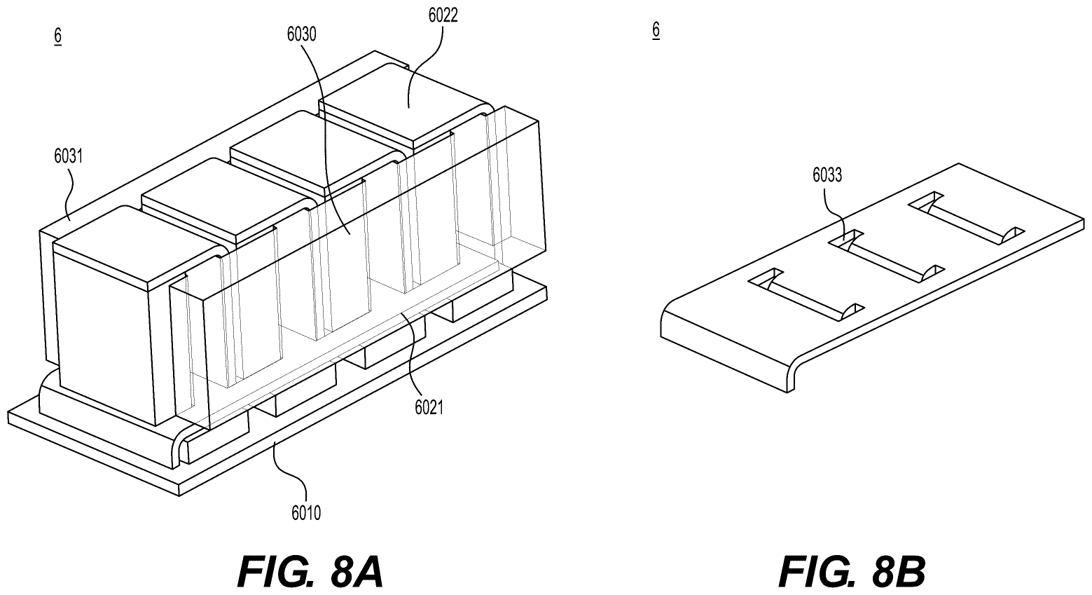

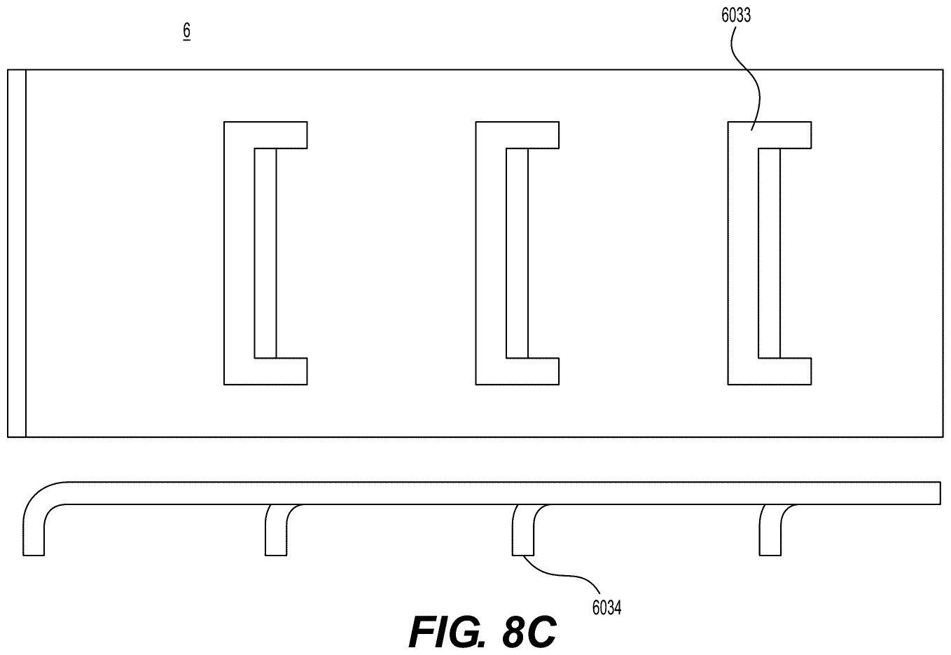

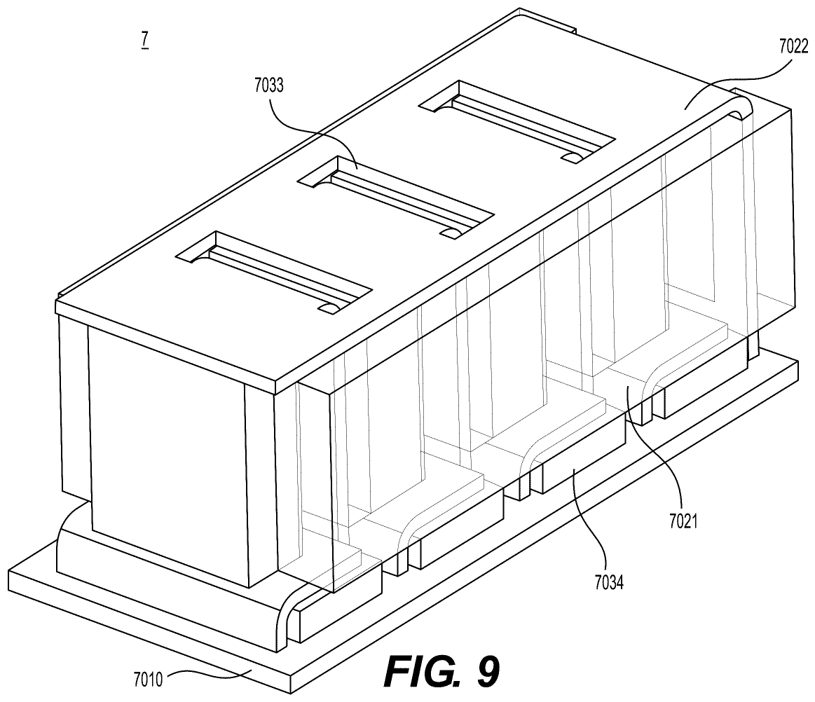

A power supply module 6 according to a sixth preferred embodiment of the present invention will be described with reference to FIGS. 8A-8C. FIG. 8A is a perspective view of the power supply module 6 according to a sixth preferred embodiment of the present invention. FIGS. 8B and 8C show perspective views of portions of the power supply module 6 according to the fourth preferred embodiment of the present invention.

As illustrated in FIG. 8A, the power supply module 6 according to the sixth preferred embodiment can be different from the power supply module 1 according to the first preferred embodiment in that multiple pillars 6030 which can be rectangular or cubic in shape are surrounded by magnetic material 6031 which can include separately provided structures having the shape of a single long side with multiple perpendicular projections which extend between pairs of the pillars 6030. Further, the upper board 6022 is defined by multiple individual structures which only directly contact the upper surfaces of the corresponding pillars 6030 while the lower board 6021 can include a single structure which includes openings 6033 into which lower portions of the upper board 6022 are able to pass through to reach the substrate 6010.

FIGS. 8B and 8C show views of the lower board 6021. The openings 6033 can include curved projections 6034 provided at a periphery of the openings 6033 which extend downwards towards an upper surface of the circuit board 6010. The openings can overlap portions of the lower surfaces of the pillars 6030. Remaining portions of the lower board 6021 can have similar structures to those of the power supply module 1 according to the first preferred embodiment. When portions of the pillars 6030 are inserted into the openings 6033, it is possible to increase a stability of the power supply module 6.

### Seventh Preferred Embodiment

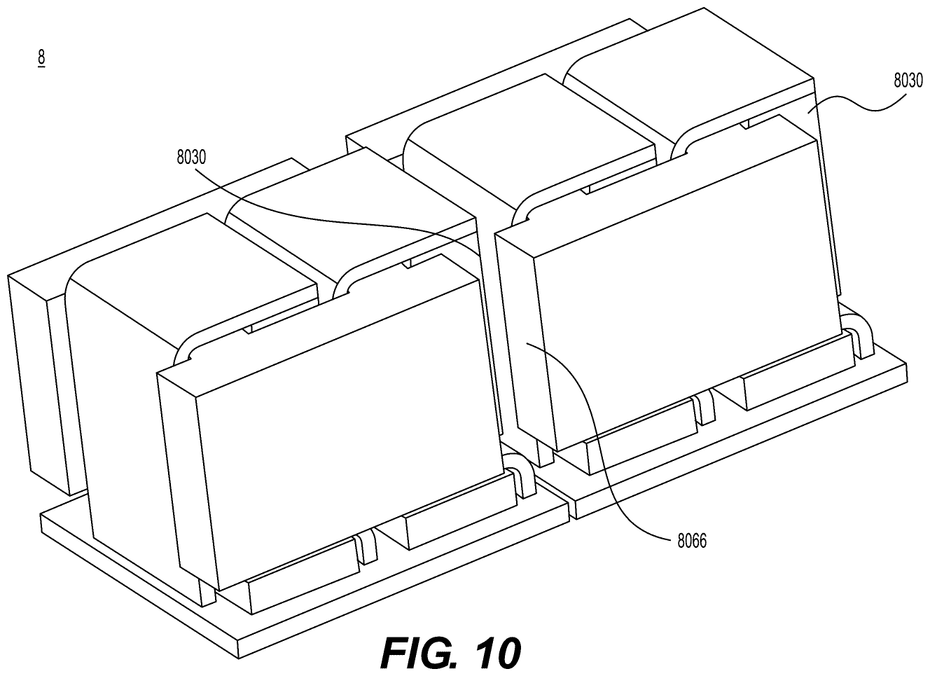

A power supply module 7 according to a seventh preferred embodiment of the present invention will be described with reference to FIG. 9. FIG. 9 is a perspective view of the power supply module 7 according to a seventh preferred embodiment of the present invention.

As illustrated in FIG. 9, the power supply module 7 according to the seventh preferred embodiment can be different from the power supply module 1 according to the first preferred embodiment in that multiple pillars 7030 which can be rectangular or cubic in shape are surrounded by magnetic material 7031 which can include separately provided structures having the shape of a single long side with multiple perpendicular projections which extend between pairs of the pillars 7030. Further, the lower board 7021 can be defined by multiple individual structures that only directly contact lower surfaces of the corresponding pillars 7030, while the upper board 7022 can include a single structure that includes openings 7033. The openings 7033 can include curved projections 7034 that extend downward between adjacent ones of the individual structures of the lower board 7021 to reach the substrate 7010. When portions of the pillars 7030 are inserted into the openings 7033, it is possible to increase the stability of the power supply module 7.

### Eighth Preferred Embodiment

A power supply module 8 according to an eight preferred embodiment of the present invention will be described with reference to FIG. 10. FIG. 10 is a perspective view of the power supply module 8 according to a ninth preferred embodiment of the present invention.

As illustrated in FIG. 10, the power supply module 8 according to the eight preferred embodiment can be different from the power supply module 1 that multiple pillars 8030 which can be rectangular or cubic in shape are surrounded by magnetic material 8031 which can include multiple structures having the shape of the Greek letter pi (π). A large gap 8066 can be defined between adjacent ones of the multiple structures of the magnetic material 8031.

The configurations of the preferred embodiments and modifications described above can appropriately be combined with each other, and effects corresponding to the respective combinations can be achieved.

It should be understood that the foregoing description is only illustrative of the present invention. Various alternatives and modifications can be devised by those skilled in the art without departing from the present invention. Accordingly, the present invention is intended to embrace all such alternatives, modifications, and variances that fall within the scope of the appended claims.

1. A power supply module comprising:
a substrate;
an electronic component provided on an upper surface of the substrate;
a lower board electrically connected with the electronic component through the substrate;
an upper board electrically connected another end of the at least one pillar opposing an end of the at least one pillar that is electrically connected with the at least one lower board, the at least one upper board being electrically connected with the substrate;
a pillar that extends between the lower board and the upper board and that includes:
a first end electrically connected with the lower board; and
a second end electrically connected with the upper board; and
a magnetic material provided around a periphery of the pillar.

2. The module according to claim 1, wherein the electronic component is thermally connected with the lower board.

3. The module according to claim 1, wherein the electronic component is thermally connected with the lower board through a thermal conductive material.

4. The module according to claim 1, wherein the lower board, the pillar, and the upper board define an inductor.

5. The module according to claim 1, wherein
the lower board is connected with the upper surface of the substrate;
the lower board includes a lower-board rising portion extending upwards from the substrate, a lower-board bent portion located on an end of the lower-board rising portion, and a lower-board flat portion extending from the lower-board bent portion along a plane parallel or substantially parallel to the upper surface of the substrate; and
an upper surface of the lower-board flat portion is connected with the first end of the one pillar.

6. The module according to claim 5, wherein an upper surface of the electronic component is thermally connected with a lower surface of the lower-board flat portion.

7. The module according to claim 6, wherein thermally conductive material is provided between the upper surface of the electronic component and the lower surface of the lower-board flat portion.

8. The module according to claim 5, wherein a surface area of the lower-board flat portion is greater than a surface area of the lower-board rising portion.

9. The module according to one of claim 5, wherein a maximum height of the electronic component is the same as or smaller than a distance between a lower surface of the lower-board flat portion and the upper surface of the substrate.

10. The module according to claim 9, wherein the electronic component is at least partially molded in a resin material.

11. The module according to claim 10, wherein a maximum height of the resin material is the same or smaller than the distance between the lower surface of the lower-board flat portion and the upper surface of the substrate.

12. The module according to claim 9, wherein the upper board includes:
an upper-board flat portion extending along a plane parallel or substantially to the upper surface of the substrate;
an upper-board bent portion provided on an end of the upper-board flat portion; and
an upper-board rising portion extending from the upper-board bent portion and electrically connected to the substrate.

13. The module according to claim 12, wherein a sum of the maximum height of the electronic component, a maximum thickness of the lower-board flat portion, and a maximum thickness of the pillar is the same as a total distance between a lower surface of the upper-board flat portion and the upper surface of the substrate.

14. The module according to claim 12, wherein a total surface area of the upper-board flat portion is larger than a total surface area of the upper-board rising portion.

15. The module according to claim 1, wherein the pillar has a cylindrical shape.

16. The module according to claim 1, wherein the electronic component includes a field-effect transistor.

17. The module according to claim 1, further comprising an additional pillar, wherein
the pillar and the additional pillar are arranged in a straight line which extends in a direction that crosses an extending direction of the lower board.

18. A power supply module comprising:
a first substrate and a second substrate;
a first electronic component provided on an upper surface of the first substrate;
a first lower board electrically connected with the first electronic component through the first substrate;
a first upper board electrically connected with the first substrate;
a first pillar that extends between the first lower board and the first upper board and that includes:
a first end electrically connected with the first lower board; and
a second end electrically connected with the first upper board;
a first magnetic material provided around the first pillar;
a second electronic component provided on an upper surface of the second substrate;
a second lower board electrically connected with the second electronic component through the second substrate;
a second upper board electrically connected with the second substrate;
a second pillar that extends between the second lower board and the second upper board and that includes:
a first end electrically connected with the second lower board; and
a second end electrically connected with the second upper board; and
a second magnetic material provided around the second pillar; wherein
the first lower board, the first pillar, the first upper board, the second lower board, the second pillar, and the second upper board are magnetically connected together.

19. The module according to claim 18, wherein the first magnetic material and the second magnetic material are fixed together.

20. The module according to claim 19, wherein the first magnetic material and the second magnetic material are provided together as a single monolithic member.
